(19) United States
(12) Patent Application Publication
(10) Pub. No.: US 2025/0100886 A1
(43) Pub. Date: Mar. 27, 2025

(54) METHODS OF FABRICATION AND USE OF CARBON NANOTUBE POLYANIONS

(71) Applicants: Jorma VIRTANEN, Massillon, OH (US); Heikki SEPPA, Helsinki (FI); Jouko VIRTANEN, Marysville, WA (US)

(72) Inventors: Jorma VIRTANEN, Massillon, OH (US); Heikki SEPPA, Helsinki (FI); Jouko VIRTANEN, Marysville, WA (US)

(21) Appl. No.: 18/897,265

(22) Filed: Sep. 26, 2024

Related U.S. Application Data
(60) Provisional application No. 63/585,714, filed on Sep. 27, 2023.

(51) Int. Cl. C01B 32/174; C09D 1/00; C09D 5/30; C09D 7/62; H05K 9/00

(52) U.S. Cl. CPC C01B 32/174; C09D 1/00; C09D 5/30; C09D 7/62; H05K 9/009; C01B 2202/06; C01B 2202/22; C01P 2006/40

(57) ABSTRACT

A method for the fabrication of carbon nanotube metal cation complexes includes activating metal particles by removing metal oxide, carbonate or some other inactivating surface layer, washing carbon nanotubes with a solvent to remove any additives or impurities that may be present, adding and mixing active metal particles and pure carbon nanotubes in a solvent that is dry, and stirring the mixture until a sample taken has a desired resistance.

### I. BACKGROUND

This application claims priority to U.S. Ser. No. 63/585,714, filed Sep. 27, 2023, entitled METHODS OF FABRICATION AND USE OF CARBON NANOTUBE POLYANIONS, the contents of which are incorporated herein by reference.

Carbon Nanotubes (CNTs) may be classified as single walled (SWNT), double walled (CWNT), or multiwalled (MWNT) nanotubes. Further subclassification may be done based on the chirality of the CNTs. Each type has a somewhat different electrical conductivity. Although one individual CNT may be an extremely good electrical conductor, the macroscopic conductance of CNTs is not good because the contact resistance between CNTs is significant. Electrons in the CNT molecules are confined in the molecular orbitals. Different CNTs have different energy levels of electrons. This means that even if an electron is traveling along a conduction path formed by several CNTs, it is continuously going up and down in its energy landscape, which means that energy is continually lost. This energy loss is manifested as an electrical resistance. Electrical resistance is also created by scattering of electrons from the atomic nuclei.

Superconductivity is fundamentally different than normal electrical conductivity. Superconductivity is characterized by two different electromagnetic properties. First, the resistance is zero, or even negative. This is possible, because in superconductors electron pairs (Cooper pairs) conduct electricity instead of single electrons. This is a major difference because Cooper pairs are bosons unlike electrons, which are fermions. Unlike electrons (Pauli exclusion principle), several bosons can occupy the same quantum state. This property is utilized in quantum computers. Second, superconductors repel magnetic fields, causing the magnetic field to go around a superconductor, which is called the Meissner effect. Material that has zero resistance, but no Meissner effect is called a perfect conductor, but not a superconductor.

These properties have some very useful applications including, but not limited to, lossless electrical wires, strong electromagnets that may be used in MRI (magnetic resonance imaging), and levitation. Long coherence length makes possible room temperature quantum computing.

Until now, no known materials exhibit superconductivity or perfect conductance at room temperature. There have been claims of room temperature (RT) superconductivity, but none has been confirmed by independent studies. More recently, there was a preliminary report that copper doped lead apatite is a RT superconductor. This is also doubtful, because several laboratories reported that they were unable to repeat the results of the original group.

### II. Summary

The purpose of the present teaching is to fill all of the molecular orbitals of the CNTs at the same energy level. This may be achieved electrochemically using electropositive metals that donate electrons to the CNTs creating CNT polyanions. Using a hilly landscape metaphor, if a freeway or railroad is made by building tunnels and bridges, there might be no up or down hills. In electrical conductivity, the superconductivity is analogous to traveling in a single energy level without resistance. This is possible because electrons form Cooper pairs that condense into a single quantum mechanical wave, in which all electrons have the same energy. A Cooper pair (or BCS pair (Bardeen-Cooper-Schrieffer pair)) is a pair of electrons (or other fermions) bound together at low temperatures in a certain manner. An arbitrarily small attraction between electrons in a metal can cause a paired state of electrons to have a lower energy than the Fermi energy, which implies that the pair is bound. In conventional superconductors, this attraction is due to the electron-phonon interaction. The Cooper pair state is responsible for superconductivity.

An electron in a metal normally behaves as a free particle. The electron is repelled from other electrons due to their negative charge, but it also attracts the positive ions that make up the rigid lattice of the metal. This attraction distorts the ion lattice, moving the ions slightly toward the electron, increasing the positive charge density of the lattice in the vicinity. This positive charge can attract other electrons. At long distances, this attraction between electrons due to the displaced ions can overcome the electrons' repulsion due to their negative charge and cause them to pair up. The rigorous quantum mechanical explanation shows that the effect is due to electron-phonon interactions, with the phonon being the collective motion of the positively-charged lattice. The energy of the pairing interaction is quite weak, of the order of 10⁻³ eV, and thermal energy can easily break the pairs. So only at low temperatures, in metal and other substrates, are a significant number of the electrons bound in Cooper pairs. Under certain conditions the CNT polyanions might be superconducting.

It is clear that RT superconductivity would be extremely useful. About 10% of the electrical energy is lost during the transfer from the power plant to the consumer. Worldwide savings would be enormous using RT superconductor. MRIs would be commonly available and cheap, if no liquid helium cooling is required. Also levitating trains and cars could be widely used leading to further savings of energy. Another application would be massive quantum computers. Even small quantum computers compete successfully with conventional supercomputers. Quantum supercomputers could do calculations that are now impossible.

CNTs have been used as additives in anticorrosive paints containing zinc or aluminum powder. In developing the present teaching, it was found that etched zinc and aluminum flakes provide better results than powders. Barium cannot be used in anticorrosive paints, because barium would be consumed very fast in wet environment. In the present teaching barium metal is used during fabrication, but the active product contains only barium cations, and not barium in a metallic form.

The present teaching describes fabrication and properties of some highly conductive materials, and some potential uses of these materials. These materials are complexes containing polyanions of graphitic materials and metal cations. More accurately graphitic materials are carbon nanotubes in the present teaching.

In one aspect of the present teaching a method for the fabrication of carbon nanotube metal cation complexes includes activating metal particles removing metal oxide, carbonate or some other inactivating surface layer, washing carbon nanotubes with a solvent to remove any additives or impurities that may be present, adding and mixing active metal particles and pure carbon nanotubes in a solvent that is dry, stirring the mixture until a sample taken has a desired resistance.

In another aspect of the present teaching, the carbon nanotubes are double walled or multi walled.

In another aspect of the present teaching, the metal particles are zinc, or aluminum flakes, and activation is performed using 2-propanol that is saturated with sodium hydroxide.

In another aspect of the present teaching, the metal particles are barium particles that are formed by mechanically cutting barium pieces smaller under inert gas or vacuum.

In another aspect of the present teaching, the mixing is performed by ultrasonic vibration or magnetic, or mechanical stirring, or any combination of these.

In another aspect of the present teaching, the desired resistance is zero, or negative resistance, when measured by a 4-point method.

In another aspect of the present teaching, the CNT polyanion complexes are used as EMI shields.

In another aspect of the present teaching, the polyanion complexes are used as stealth coatings.

In another aspect of the present teaching, the polyanion complexes are used to harvest electromagnetic energy from the surroundings.

In another aspect of the present teaching, the polyanion complexes are used in electrical wires.

Still other benefits and advantages of this disclosure will become apparent to those skilled in the art to which it pertains upon a reading and understanding of the following detailed specification.

### III. Brief Description of the Figures

The disclosure may take physical form in certain parts and arrangement of parts, aspects of which will be described in detail in this specification and illustrated in the accompanying figures which form a part hereof.

FIG. 1. Schematic depiction of CNT-metal cation complex of the present teaching.

FIG. 2. Schematic of 4-point measurement.

FIG. 3. The graph depicting the resistance of barium-DWNT complex of the present teaching as a function of the current.

FIG. 4. The graph depicting the voltage of barium-MWNT complex of the present teaching as a function of the current.

FIG. 5 shows a measured graph of the resistance of Ba-MWNT complex as a function of the current.

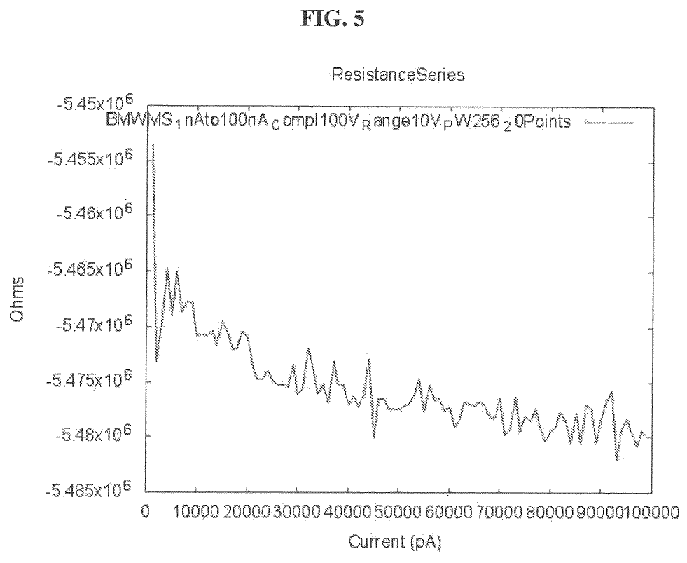

FIG. 6 shows a representation of the Meissner effect.

### IV. Definitions

Moiety—a part of a molecule.

Anion—an ion that has a negative charge.

Polyanion—an anion that has multiple negative charges, in this context more than ten negative charges.

Complex in chemistry—an assembly of molecules and ions that may not have a well defined and known structure, but only the average structure is known, or can be estimated.

Quantum entanglement—a phenomenon in which the quantum states of two or more quantum particles are correlated even, when the particles are not in a close proximity.

### IV. Detailed Description

Carbon has a lower electrochemical redox potential than most metals, especially alkali, and earth alkali metals. In Table 1 shows the metals that have a higher negative electrochemical potential than carbon. In the present teaching, carbon is typically graphite, but other graphitic materials are expected to have almost the same electrochemical potential (about 0.1 V). The exact value is difficult or even impossible to measure, because graphitic materials are insoluble in solvents. The metals in Table 1 are expected to transfer electrons to the CNTs if the components are in close contact. Transferred electrons may be single electrons, Cooper pairs, or quantum entangled electrons. These are all known in various systems, but not necessarily at room temperature. Single electrons carry electric current in normal conductors, while Cooper pairs carry current in superconductors.

Every carbon atom has six electrons. Four of which are valence electrons used to form covalent bonds. In aromatic compounds carbon is sp² hybridized, allowing formation of three bonds, two single bonds and one double bond, in which also the unhybridized p orbital is involved. The three valence bond electrons of sp² are tightly bound, but electrons in the p orbital may be delocalized. The angle between these bonds is 120°, which naturally leads to the formation of hexagonal rings. The unlocalized p orbital electrons are also called π orbitals. These make graphitic compounds electrically conductive. All the electrons are still valence electrons located in bonding orbitals. Quantum mechanically, each molecule has the same amount of bonding and antibonding orbitals. Normally antibonding orbitals are empty. Electrons in antibonding orbitals are not associated with any specific atom or bond and are accordingly free to move. One aspect of the present teaching is to put a very large number of electrons into antibonding orbitals in order to create conducting materials, including superconductors. The number of antibonding orbitals is that same as the number of bonding orbitals. Thus, the number of electrons in antibonding orbitals can be very large. At some point the molecule would become unstable when antibonding orbitals are filled with electrons. However, it would take four extra electrons for each carbon atom to totally fill all of the antibonding orbitals, which would take a million or more electrons to fill the antibonding orbitals of a CNT. In the polyanions of the present teaching the goal is to have 1000-100,000 extra electrons in one carbon nanotube. This is an approximate goal, and the actual values may deviate. These antibonding electrons are not associated with any chemical bonds and are delocalized, i.e., they are free to move.

W. A. Little proposed that an organic conductor may become superconducting, if polarizable moieties are attached along the conduction path. These moieties could stabilize Cooper pairs. V. Ginzburg proposed that Cooper pairs would be more stable in a low dimensional system compared to a 3D-system. CNTs allow combination of these two principles. CNTs are low dimensional. All atoms are three dimensional, so all molecules are three dimensional. However, electron movement in a molecule may be dimensionally limited if the atom nuclei are located in one or two dimensional lines or surface. These molecules are called quasi-one or -two dimensional. Examples are polyacetylene and graphene. CNTs are comparable to graphene in this regard. CNTs can be considered rolled graphene, and are best classified as quasi two dimensional, and not quasi one dimensional as often done in the literature. Atoms that do not take part in electron transport may still be outside this line or surface. According to Ginzburg these kind of structures are favorable for the superconductivity.

Cooper pairs are used for superconductivity. In traditional superconductivity the Cooper pairs are stabilized by phonons. W. A. Little proposed that polarizable moieties could also stabilize Cooper pairs and do it so well that room temperature superconductivity would be possible. Adding polarizable moieties into the conduction path would be a difficult chemical problem. First, there might be damage or disturbance to the conduction path. Second, it might be difficult to achieve a high enough density of the polarizable moieties. In the present teaching metal cations are used as polarizable moieties. They are held on the surface of a CNT molecule by electrostatic force, and do not damage the structure of the CNT. Table 2 has polarizabilities of some metal atoms. Although Cooper pairs contain two electrons, the theory does not require that the stabilization charge is 2+, but can be any positive charge. However, in one aspect of the present teaching both electrons come from the same metal atom, and the charge of the cation is 2+. Thus, looking at Tables 1 and 2, barium is a two electron donor that also has a high polarizability. Barium was used for the experimental verification of the present teaching. It should be understood that many other metals, including zinc and aluminum give analogous results. Cesium has a higher polarizability than barium, and also a more negative redox potential. It is expected that cesium-CNT complexes would have analogous properties to Ba-CNT complexes.

TABLE 1
Redox potential of some important metals that
have potential more negative than −2.9 V.

| Sr+e | Sr(s) | −4.10 V |
|---|---|---|
| Ca+e | Ca(s) | −3.8 |
| Th+e | Th³⁺ | −3.6 |
| Pr+e | Pr²⁺ | −3.1 |
| Li+e | Li(s) | −3.04 |
| Cs+e | Cs(s) | −3.03 |
| Er+e | Er²⁺ | −3 |
| Rb⁺ | Rb(s) | −2.98 |
| K⁺ | K | −2.93 |
| Ba²⁺+2e | Ba(s) | −2.91 |
| Sr²⁺+2e | Sr(s) | −2.9 |
| Ca²⁺+2e | Ca(s) | −2.87 |
| Eu²⁺+2e | Eu(s) | −2.91 |

TABLE 2
Polarizabilities of alkali and earth alkali metals
(Frankium and radium are not included).

| | |
|---|---|
| Cs | 400 |
| Rb | 318 |
| K | 290 |
| Ba | 272 |
| Sr | 195 |
| Li | 164 |
| Na | 163 |
| Ca | 159 |
| Mg | 72 |

If zinc and aluminum flakes could be separated from CNTs after the reaction, the conduction properties of the CNT-metal complexes would remain intact. The separation can be difficult because the sizes of the metal flakes are close to CNTs. Common metal coating methods could also be used, including, but not limited to, direct evaporation, laser or argon ablation of metal, and atomic layer epitaxy.

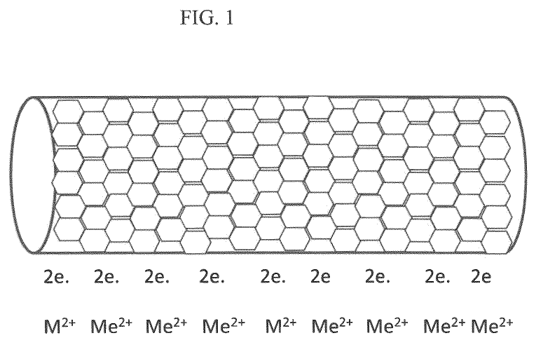

Some of the most electropositive metals are also the most polarizable. This opens the possibility of using the reaction between these metals and CNTs to attach metal cations onto the CNT surface. At the same time, the conduction bands of the CNTs will be occupied by electrons, and polarizable cations will cover the surface of the CNTs. The structure of the CNTs should remain intact. Thus, the Little polymer may be created in one simple process. These compounds can be considered organometallic compounds, in which the bond between the metal cation and the CNT anion is an ionic bond. Thus, they can also be called salts. Schematic of these salts is shown in FIG. 1. In FIG. 1, the metal cations are only on the lower side of the CNT, but it is to be understood that they may be symmetrical on the surface of the CNT. The length of a CNT can be about 5 μm (5000 nm), and the diameter can be about 10 nm. Thus, the surface area is about 150,000 nm². If the surface concentration of metal cations is 0.1/nm², the total number of metal cations would be about 15,000, and the charge of the CNT in FIG. 1 would be about-30,000 elementary charges. These compounds are called complexes. Even if the CNT might not be superconducting, it would be an excellent conductor, and contact resistance between the CNTs would be minimal. Metal cations may also connect two CNTs together, such as a bivalent metal cation can bind two chloride anions. In this case multiple metal cations may bind CNTs. This helps to minimize or eliminate the contact resistance.

In the first experiments CNTs were dispersed into epoxy (Epon828), with various amounts of zinc dust being added, and a hardener. Contrary to expectations, a small amount of zinc dust increased resistance compared to neat CNTs. One explanation is that electrons were transferred from zinc to the CNT, but only at the point of contact. The positive charge in the zinc particle kept the electrons localized near the contact point. This created Coulombic blockade for the conducting electrons. CNTs are quite stiff. The curvature often seen in electron microscope images is due to structural defects that were formed during fabrication process, and not bending that happened later. If the curvature happens in one direction, the CNT is still planar. Then the CNT molecule may fit flat on the surface of a metal flake. The transfer of electrons could be uniform for the whole length of the CNT molecule. This was supported by experiments, in which zinc or aluminum flakes were used. In order to make electron transfer more effective, the flakes were etched to remove the oxide layer that forms spontaneously on the surface of these metals. The oxide layer is typically about 5 nm when the oxide starts to protect the metal against further oxidation.

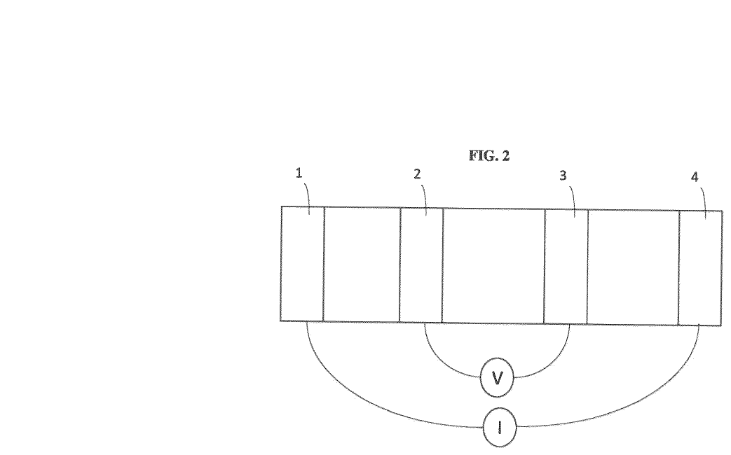

The resistance measurement of superconductors is not as straightforward as one might think. The Cooper pairs have lower energy than normal Fermi level electrons in metals. This means that electron transfer from a superconductor to a positive electrode requires energy, because the Cooper pair must be broken into two normal electrons. Thus, there is a significant contact resistance in the measurement circuit. This can be eliminated using 4-point measurement, in which a power source is connected with electrodes 1 and 4, and voltage is measured between electrodes 2 and 3 (FIG. 2). Because the circuit necessarily contains different metals, and metal oxide layers, there can be asymmetrical electromotive forces. These can be eliminated by using an alternating square pulse and averaging the voltage over several cycles. Typically, 100 voltage measurements were made for each current. The resistance was calculated using the average of all voltages.

Two types of slides were used for electrical measurements, 1′×3′ glass slides that had four evaporated gold zones (FIG. 2), or plastic coated cardboard slides that had four copper tapes evenly separated. Electrical measurements were performed with Keithley picoamp power source (Model 6221), and nanovolt meter (Model 2182A). Meters were controlled, and data collected by a self-written computer code. The starting current could be chosen between 1 pA and 100 mA. The end current was chosen between these same values. The current was changed stepwise, and the magnitude of a step could be freely chosen. So called delta mode was typically used. A power source generates an alternating square wave. The voltage was measured both at positive and negative current, taking into account the direction of the current. Typically, 100 measurements were made at each current value, and all values were tabulated, but for the calculation of the resistance the average value of the voltage was used. A pulse width of the square wave could be chosen from the minimum of 1 ms to several seconds; sometimes 16,384 ms (about 16 s) was used that is practically equal to DC.

Typically, the first measurement was done between 10 pA and 1 nA in 10 pA steps, and the second between 1 nA and 100 nA in 1 nA steps. Low currents do not disturb the system, but voltage measurement is noisy. Higher currents give more accurate results. There might be two currents-electronic and ionic current. Electrons and ions move in opposite directions, which leads to destabilization of the system near terminal electrodes.

Resistances were negative for samples containing zinc, aluminum, barium, and CNTs. Fabrication of samples is described in Examples 1 and 2. Negative resistance is often associated with superconductivity, and has actually been observed in superconducting vanadium nanowires. In normal resistance, electrons lose energy while they hit atomic nuclei. As a result, the kinetic energy of the electrons is converted into electromagnetic radiation. In a reverse process, electrons absorb electromagnetic radiation and gain kinetic energy. Faster speed shows as a negative potential in 4-point measurement. This can only happen if the resistance is practically zero at the beginning.

An Al-flake sample was measured in the dark and in daylight. Resistances were −5 kOhm, and −10 kOhm, respectively. Ba samples had resistances between −500 kOhm, and −20 MOhm depending on the pulse width from 1 ms to 1,024 ms. It is expected that background IR-radiation is a relevant factor in increasing electron energy, because the energy of the radiation decreases when the wavelength increases, and longer wavelength radiation would have much a smaller effect on the negative resistance. The measurements show that these materials have potential application in collecting background electromagnetic radiation, and converting it directly into electrical energy like solar cells convert light energy into electricity. However, the materials of the present teaching have a very wide spectrum that includes all wavelengths from visible light to radio waves.

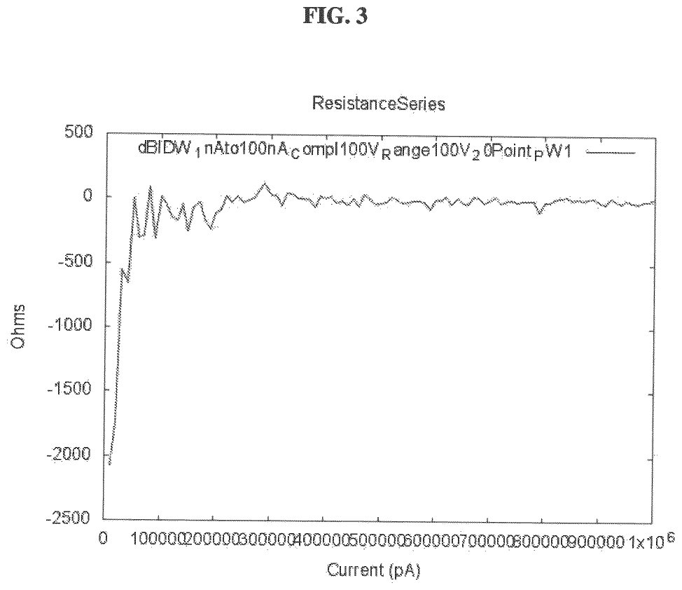

FIG. 3 shows a measured graph of the resistance of Ba-DWNT complex as a function of the current. The resistance is very close to zero Ohm in the whole range. There is a small fluctuation above and below zero level.

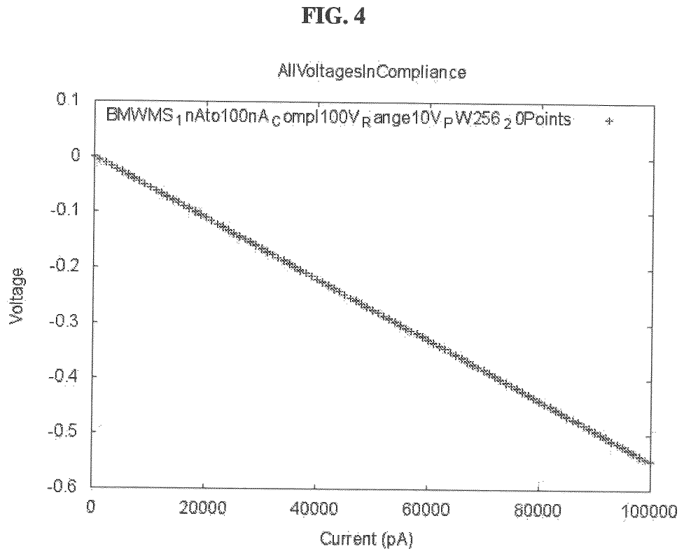

Similarly, FIG. 4 shows a measured graph of the resistance of Ba-MWNT complex as a function of the current. The resistance is strongly negative (about-5.5 MOhm).

### Example 1

200 mg NaOH was put into an Erlenmeyer flask, and 100 g 2-propanol was added and stirred with a magnetic mixer 1 h. This was then filtered through a filter paper. Into the filtrate was added 20 g of aluminum flakes, stirred 15 min with a magnetic mixer, filtered through a filter paper under Ar, and washed with 100 g of 2-propanol, and then with 100 g of toluene. During washing, aluminum flakes were mixed with a steel spatula. The washing steps were performed under Ar. Al flakes were mixed with 100 g toluene, and 20 f of Sokleen. 1 g of molecular sieve was heated at 120° C. for one hour, and cooled at RT, and then added into the Al flake dispersion.

### Example 2

Barium was received in about 5 mm or 1 cm chunks (10 g). 5 mm pieces were used as such. 1 cm chunks were cleaved into two approximately equal 5 g pieces with pliers or side cutters under Ar so that a metallic surface was clearly visible. Two 5 g pieces were put into 100 g toluene plus 20 g Sokleen® (Midwest Industrial Supply Inc.). Also 1 g of molecular sieve and 2 g of MWNTs (Arkema) was added. The mixture was first ultrasonically vibrated 2 min, and then stirred 72 h under Ar using a magnetic mixer. 3 g Dimethyl dimethoxysilane and 1 g phenyl trimethoxy silane were added. After a second ultrasonic vibration the mixture was ready for use. Two barium pieces were picked up with tweezers. Silanes form a thin protective silicone film on top of the CNT layer due to the water vapor in the air. Sokleen® acts as an inert lubricant that helps the orientation of the CNTs and also provides a thin protective layer around them.

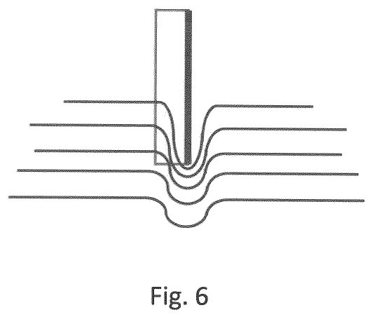

With reference now to FIG. 6, superconductors display the Meissner effect, wherein the superconductors repel the magnetic field so that the field lines go around the superconductor. The density of the field increases near the edge and is very small on top of the superconductor. The strength of earth's magnetic field was measured with a Bell magnetometer 8010. The earth's magnetic field is 34 mGauss. On the edge of a slide that was coated with BaMWT the field was 40 mGauss, and in the center of the slide the field was 0 mGauss. This indicates that BaMWNT has the Meissner effect.

Clause 1. A Method for the fabrication of carbon nanotube metal cation complexes, in which
a. Metal particles are activated by removing metal oxide, carbonate or some other inactivating surface layer.
b. Carbon nanotubes are washed with a solvent to remove any additives or impurities that may be present.
c. Active metal particles and pure carbon nanotubes are added and mixed in a solvent that is dry.
d. Mixture is stirred until a sample taken has a desired resistance.

Clause 2. A method of Clause 1, in which the carbon nanotubes are double walled or multi walled.

Clause 3. A method of Clauses 1 or 2, in which the metal particles are zinc, or aluminum flakes, and activation is performed using 2-propanol that is saturated with sodium hydroxide.

Clause 4. A method of any of Clauses 1-3, in which the metal particles are barium particles that are formed by mechanically cutting barium pieces smaller under inert gas or vacuum.

Clause 5. A method of any of Clauses 1-4, in which the mixing is performed by ultrasonic vibration or magnetic, or mechanical stirring, or any combination of these.

Clause 6. A method of any of Clauses 1-5, in which the desired resistance is zero, or negative resistance, when measured by 4-point method.

Clause 7. Use of the CNT polyanion complexes in any of clauses 1-6 as EMI shields.

Clause 8. Use of the polyanion complexes in any of clauses 1-6 as stealth coatings.

Clause 9. Use of the polyanion complexes in any of clauses 1-6 to harvest electromagnetic energy from the surroundings.

Clause 10. Use of the polyanion complexes in any of clauses 1-6 in electrical wires.

Non-limiting aspects have been described, hereinabove. It will be apparent to those skilled in the art that the above methods and apparatuses may incorporate changes and modifications without departing from the general scope of the present subject matter. It is intended to include all such modifications and alterations in so far as they come within the scope of the appended claims or the equivalents thereof.

Having thus described the present teachings, it is now claimed:

1. A method for the fabrication of carbon nanotube metal cation complexes, comprising the steps of:
activating metal particles by removing an inactivating surface layer;
washing carbon nanotubes with a solvent to remove any additives or impurities;
adding active metal particles and pure carbon nanotubes;
mixing in a dry solvent; and
stirring the mixture to obtain a desired resistance.

2. The method of claim 1, wherein the carbon nanotubes are double walled or multi walled, wherein the inactivating layer is a metal oxide or a carbonate.

3. The method of claim 1, wherein the metal particles are zinc, or aluminum flakes, and activation is performed using 2-propanol that is saturated with sodium hydroxide.

4. The method of claim 1, wherein the metal particles are barium particles that are formed by mechanically cutting barium under inert gas or vacuum.

5. The method of claim 1, wherein the mixing is performed by ultrasonic vibration, magnetic stirring, or mechanical stirring, or any combination thereof.

6. The method of claim 1, wherein the desired resistance is zero, or negative resistance, when measured by a 4-point method.

7. An EMI shield created by the method of claim 1.

8. A stealth coating created by the method of claim 1.

9. The method of claim 1, wherein electromagnetic energy is harvested from surroundings.

10. An electric wire created by the method of claim 1.
